(19) United States
(12) Patent Application Publication
(10) Pub. No.: US 2023/0375108 A1
(43) Pub. Date: Nov. 23, 2023

(54) STUD-MOUNTABLE CABLE RETENTION APPARATUS AND SYSTEM

(71) Applicant: UBICQUIA, INC., FORT LAUDERDALE, FL (US)

(72) Inventors: Claudio Santiago Ribeiro, Evanston, IL (US); Elliott Earl Murray, Plantation, FL (US); Patrick Stuart Claeys, Weston, FL (US); Travis Ronald Coleman, Sunrise, FL (US); Cesar Eduardo Nunez, Miramar, FL (US); Luisa A. Suzuki, Cedar Park, TX (US)

(21) Appl. No.: 18/201,137

(22) Filed: May 23, 2023

Related U.S. Application Data
(60) Provisional application No. 63/344,999, filed on May 23, 2022.

(51) Int. Cl. F16L 3/127; F16L 3/13; F16L 3/26

(52) U.S. Cl. CPC F16L 3/127; F16L 3/13; F16L 3/26

(57) ABSTRACT

A stud-mountable cable retention apparatus and system include a cable retention member, a stud engagement member defining a cavity therein, and a body member interconnecting the cable retention member and the stud engagement member. The cable retention member may be generally open-ended (e.g., C-shaped or U-shaped) and formed or partially formed of a flexible and resilient material. The cavity of the stud engagement member may be generally cylindrically shaped. The cable retention apparatus may also include an adjustable fastening member positioned about a periphery of the stud engagement member. The cable retention apparatus may further include one or more cable guide members connected at one end to the body member and extending away from the body member in one or more predetermined directions. The cable retention system may include two or more cable retention devices or apparatus interconnected by one or more cable guide members.

### CROSS-REFERENCE TO RELATED APPLICATIONS

The present application claims the benefit of and priority upon U.S. Provisional Patent Application No. 63/344,999, which was filed on May 23, 2022, and is incorporated herein by this reference as if fully set forth herein.

### TECHNICAL FIELD

The present disclosure generally relates to cable retention devices. More particularly, but not exclusively, the present disclosure relates to stud-mountable/post-mountable cable retention apparatus and systems.

### BACKGROUND

As is known, many different types of electronic devices use cables or wires for various purposes. In some instances, the cable location or positioning may significantly alter or degrade functionality of the electronic devices themselves or the signals carried over the cables or wires. The ease of access for installation, repair, or removal to such cables may also become an issue for workers in the field. Furthermore, mounting such cables may be difficult for installers because installation may require a variety of tools.

Rogowski coils are specialized cables used for measuring current in electrical power applications and are particularly sensitive to their placement around conductors. Improper positioning of a Rogowski coil relative to a monitored conductor may alter the accuracy and reliability of current measurements reliant on such device. Furthermore, in instances where there are many cables in use and limited space, an efficient and stable cable mounting method and apparatus may improve overall installation, operation, performance, and reliability in connection with the intended use of such cables.

All of the subject matter discussed in the Background section is not necessarily prior art and should not be assumed to be prior art merely as a result of its discussion in the Background section. Recognition of problems in the prior art discussed in the Background section or associated with such subject matter should not be treated as prior art unless expressly stated to be prior art.

### SUMMARY

According to one exemplary embodiment of the present disclosure, a stud-mountable cable retention apparatus includes a cable retention member, a stud engagement member defining a cavity therein, and a body member interconnecting the cable retention member and the stud engagement member. In some embodiments, the cable retention member is open-ended and may be generally C-shaped or U-shaped. In other embodiments, the cavity of the stud engagement member may be generally cylindrically shaped. The cable retention member may be formed of a flexible, pliable, or resilient material, such as silicone, rubber, or silicone rubber. Alternatively, the cable retention member may be formed from plastic or another non-conductive material.

In other embodiments, portions of the cable retention apparatus may have a high coefficient of friction so as minimize movement of the apparatus or a retained cable once installed.

In some other embodiments, the cable retention apparatus may also include a support member that interconnects the body member and an end portion of the cable retention member. In further embodiments, the cable retention apparatus may further or alternatively include a stop member arranged within the cavity of the stud engagement member, where the stop member is positioned a predetermined distance from an opening of the cavity. In still other embodiments, the cable retention apparatus may also or alternatively include a flange member coupled to an end of the stud engagement member so as to encircle an opening of the cavity of the stud engagement member.

In some embodiments, the stud engagement member may further or alternatively include at least one rib element on an outside surface of the stud engagement member. In other embodiments, a wall of the cavity of the stud engagement member may include a plurality of ribs, bumps, or other protrusions to assist with securing the stud engagement member to a stud, such as a post, a threaded end of a bolt, a dowel, a head of a bolt, a nut, or any other protrusion.

In further embodiments, a diameter of the cavity of the stud engagement member may be approximately equal to the smallest diameter of a stud to which the cable retention apparatus will be mounted.

According to another exemplary embodiment of the present disclosure, a stud-mountable cable retention system may include a cable retention member (which may open-ended or generally C-shaped), a stud engagement member defining a cavity therein (which cavity may be generally cylindrically shaped), a body member interconnecting the cable retention member and the stud engagement member, and an adjustable fastening member positioned about a periphery of the stud engagement member. In some embodiments, the adjustable fastening member may be a ratchet-style clamp. In other embodiments, the cable retention system may further or alternatively include a support member interconnecting the body member and an end portion of the cable retention member.

In some other embodiments, the cable retention system may further or alternatively include a cable guide member that connects at one end to the body member and extends away from the body member in a predetermined direction. In further embodiments, the cable retention system may include more than one cable guide member. For example, the system may include a first cable guide member connected at one end to the body member and extending away from the body member in a first predetermined direction and a second cable guide member connected at one end to the body member and extending away from the body member in a second predetermined direction.

According to a further exemplary embodiment of the present disclosure, a cable retention system may include a plurality of stud-mountable cable retention devices and at least one cable guide member interconnecting a pair of the cable retention devices. According to this embodiment, each cable retention device may include a cable retention member, a stud engagement member defining a cavity therein, and a body member interconnecting the cable retention member and the stud engagement member.

In some embodiments, the plurality of cable retention devices may include three cable retention devices and the at least one cable guide member may include two cable guide members. In such embodiments, a first cable guide member may be arch-shaped and interconnect a first cable retention device and a second cable retention device and a second cable guide member may be arch-shaped and interconnect the second cable retention device and a third cable retention device. In other embodiments, each cable retention device may further or alternatively include an adjustable fastening member positioned about a periphery of the stud engagement member.

In some other embodiments, a diameter of the cavity of the stud engagement member may be approximately equal to the smallest diameter of a threaded end of a bolt used to fasten a primary conductor bushing within a pad-mounted distribution transformer.

### BRIEF DESCRIPTION OF THE DRAWINGS

Non-limiting and non-exhaustive embodiments are described with reference to the following drawings, wherein like reference numerals refer to like parts throughout the various views, unless otherwise specified. The sizes and relative positions of elements in the drawings are not necessarily drawn to scale. For example, the shapes of various elements are selected, enlarged, and positioned to improve drawing legibility. The shapes of the elements as drawn have been selected for ease of recognition in the drawings.

FIG. 1A is a left side view of a stud-mountable cable retention apparatus, in accordance with exemplary embodiments of the present disclosure.

FIG. 1B is a right view of the stud-mountable cable retention apparatus of FIG. 1.

FIG. 1C is a front view of the stud-mountable cable retention apparatus of FIG. 1.

FIG. 1D is a rear view of the stud-mountable cable retention apparatus of FIG. 1.

FIG. 1E is a bottom view of the stud-mountable cable retention apparatus of FIG. 1.

FIG. 2 is a perspective view of a stud-mountable cable retention system, in accordance with exemplary embodiments of the present disclosure.

FIG. 3 is a top perspective view of a cable retention system, in accordance with other exemplary embodiments of the present disclosure.

FIG. 4A is a top perspective view of the cable retention system of FIG. 3 showing the cable retention system in use to retain a cable, in accordance with an exemplary embodiment of the present disclosure.

FIG. 4B is a bottom perspective view of the cable retention system of FIG. 3 showing the cable retention system in use to retain a cable.

FIG. 4C is an inverted bottom perspective view of the cable retention system of FIG. 3 showing the cable retention system in use to retain a cable.

FIG. 5 is a top perspective view of an alternative stud-mountable cable retention system showing the cable retention system in use to retain a cable, in accordance with further exemplary embodiments of the present disclosure.

FIG. 6 illustrates an exemplary use of the cable retention system of FIG. 3 to retain a Rogowski coil around a primary conductor bushing in a pad-mounted distribution transformer, including an enlargement of one of the transformer's primary conductor bushings and its attachment bolts, and an enlargement of another one of the transformer's primary conductor bushings with the Rogowski cable secured about the bushing using the cable retention system, in accordance an embodiment of the present disclosure.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring descriptions of the embodiments.

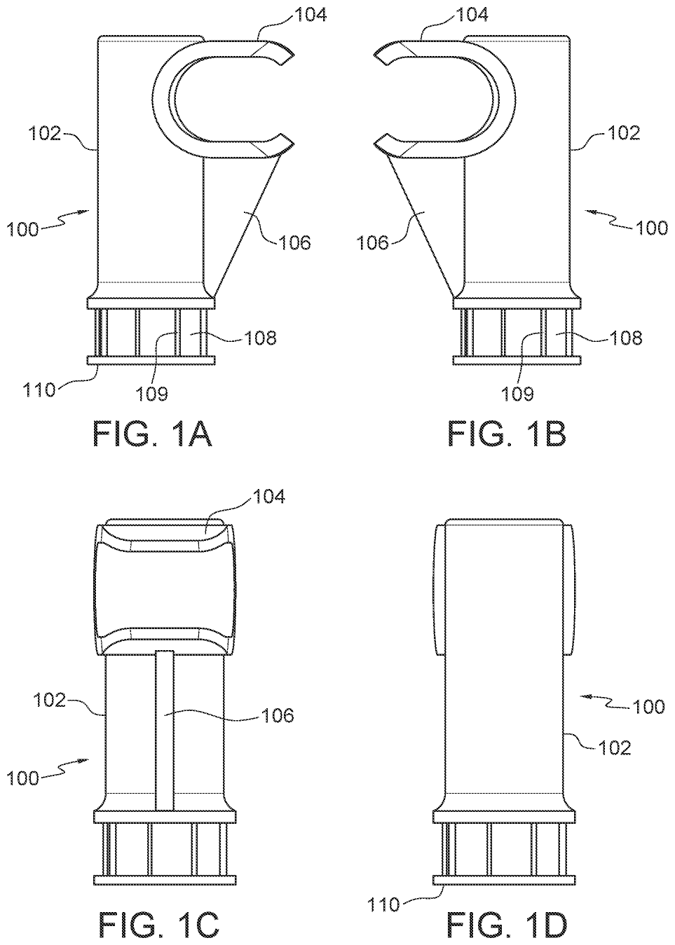

Referring to FIGS. 1A-1E, a stud-mountable cable retention apparatus 100 is illustrated in several views in accordance with one exemplary embodiment of the present disclosure. The cable retention apparatus 100 includes a cable retention member 104, a stud engagement member 108, and a body member 102 interconnecting the cable retention member 104 and the stud engagement member 108. The stud engagement member 108 defines a cavity 114 therein, which may be generally cylindrically shaped or otherwise shaped to fit over an applicable stud. In some embodiments, the cable retention member 104 is open-ended and may be generally C-shaped or U-shaped. The cable retention member 104 may be formed from a flexible and resilient material, such as silicone, rubber, or silicone rubber. Alternatively, the cable retention member 104 may be formed from plastic or another non-conductive material.

In some embodiments, not only is the cable retention member 104 made of silicone or another flexible and resilient material, but the entire cable retention apparatus 100 may be made of such material. In other embodiments, certain portions of the cable retention apparatus 100, such as the cable retention member 104 and the stud engagement member 108, may constructed of a material that is flexible, resilient, or pliable, such as silicone rubber, while other portions of the cable retention apparatus 100 are made of one or more different materials.

In some embodiments, portions of the cable retention apparatus 100 may have a high coefficient of friction. Such portions may mean certain elements or members of the cable retention apparatus 100 or, in other instances, may mean that a surface or coating of an element or member of the cable retention apparatus 100 has a high coefficient of friction. A “high coefficient of friction” in the context of the present disclosure means a coefficient of friction of greater than 0.8, for example, when in contact with a dry cable. The coefficient of friction (COF) is an empirically determined quantity, which has to be measured experimentally and cannot be found through calculations. Rougher surfaces tend to have higher effective COF values. Both static and kinetic COFs depend on the pair of surfaces in contact. A “high coefficient of friction” between the stud engagement member 108 and a stud, such as the threading or threaded portion of a bolt, may be lower than 0.8 so long as surfaces avoid rotational slippage, but generally a COF value at or above 0.8 will serve the purposes of the present disclosure.

In some embodiments, the cable retention apparatus 100 may include a support member 106 that interconnects the body member 102 and an end portion of the cable retention member 104 (e.g., the flatter portion of a C-shaped cable retention member, as illustrated in FIGS. 1A-1C). When included, the support member 106 may support the retention and weight of a cable held by the cable retention member 104. The wall structure of the support member 106 should be sturdy enough to support the cable retention member 104 and any cable (such as a Rogowski cable) that might be inserted and retained by the cable retention member 104. This ensures that the bottom part of the cable retention member 104 does not bend downward and deform causing the retained cable to come loose from the cable retention member 104.

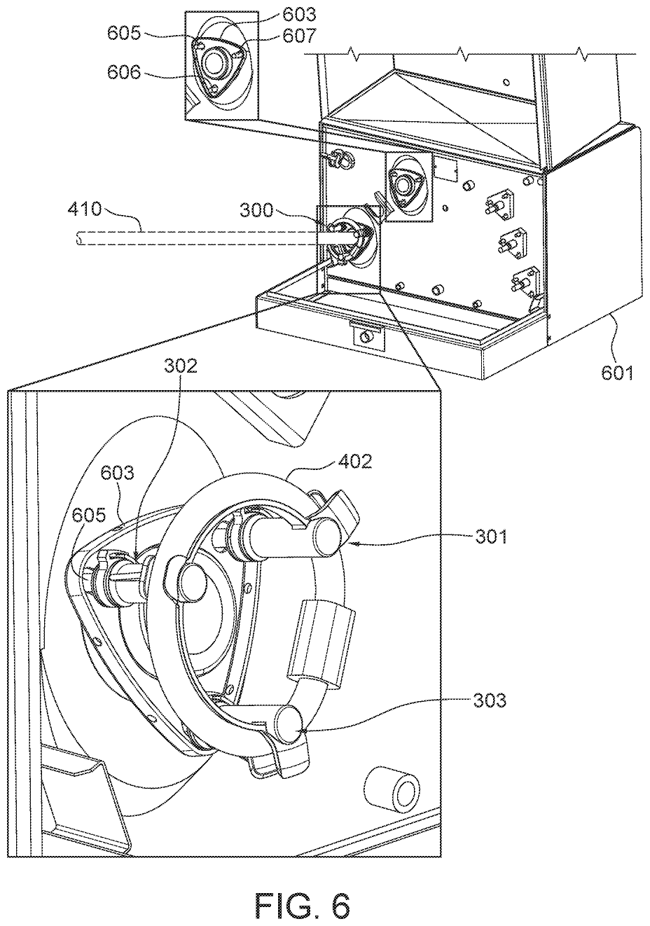

In some embodiments, the cable retention apparatus 100 may further or alternatively include a stop member 111 arranged within the cavity 114 of the stud engagement member 108. When included, the stop member 111 is positioned a predetermined distance from an opening of the cavity 114. The stop member 111 may be configured so that its distance from the opening of the cavity 114 allows the stud engagement member 108 to be appropriately placed upon a stud (as shown in FIG. 6) to enable a suitable engagement and retention between the stud engagement member 108 and the stud for different size studs, without damaging the cable retention apparatus 100. In some embodiments, the cable retention apparatus 100 may further or alternatively include a flange member 110. When included, the flange member 110 may be coupled to an end of the stud engagement member 108 so as to encircle an opening of the cavity 114 of the stud engagement member 108. The support member 106, the flange member 110, and the stop member 111 may all be integrally formed (e.g., molded) together with the formation of the cable retention member 104, the body member 102, and the stud engagement member 108.

In some embodiments, the stud engagement member 108 may further or alternatively include at least one rib element 109 on an outside surface of the stud engagement member 108. In some embodiments, a wall of the cavity 114 inside the stud engagement 108 may further or alternatively include a plurality of protrusions 113 around its periphery. The geometries illustrated in FIGS. 1A-1E for the optional rib elements 109, the optional protrusions 113, and the optional stop member 111 may be chosen to be core out features to facilitate making the cable retention apparatus 100 as an insert molded part. The geometries illustrated in FIGS. 1A-1E for the optional rib elements 109, the optional protrusions 113, and the optional stop member 111 may help keep the same wall thickness throughout the entire cable retention apparatus 100. The external rib elements 109 may also enable better gripping for an installer when placing the cable retention apparatus 100 on a stud. The external rib elements 109 may further serve to prevent an adjustable fastener, such as a ratchet-style clamp, from rotating around the stud once the fastener is set in place around a stud. The cavity wall protrusions 113 may be included for fabrication purposes to facilitate creating a generally uniform thickness of the stud engagement member 108 when the cable retention apparatus 100 is molded from, for example, silicone rubber. Such protrusions 113 may also improve the friction or gripping force of the stud engagement member 108 after positioning on a stud, such as a post, the threaded end of a bolt or screw (e.g., bolt/screw threading), a dowel, or any other rigid projection.

In some embodiments, a diameter of the cavity 114 of the stud engagement member 108 is approximately equal to the smallest diameter of a stud to which the cable retention apparatus 100 will be mounted. A stud in the context of the disclosed embodiments may be a bolt, a threaded end of a bolt, the head of a bolt, an end of a post, boss, pole, dowel, a rigid projection, a beam, or any other item or element that may be mounted. In other words, a stud in the context of the present disclosure may be any protrusion or rigid projection onto which the cable retention apparatus 100 may be mounted.

In some embodiments, the stud engagement member 108 may be constructed of a material providing sufficient spring force or gripping strength to avoid rotation of the cable retention apparatus 100 upon mounting the stud engagement member 108 on a stud. In some embodiments, an additional fastening mechanism, such as a clasp, clamp, cinching device, or ratcheting device, may be placed on the outside periphery of the stud engagement member 108 to improve the gripping strength or coefficient of friction between the engagement member 108 and the stud to avoid rotation of the cable retention apparatus 100 upon mounting.

In some embodiments, the cavity 114 of the stud engagement member 108 may have a wall or walls such that the geometrical configuration of the cavity 114 matches or substantially matches the geometrical configuration of the stud (e.g., a thread or a bolt head structure, such as a hex or star shape for the bolt or bolt head) to avoid rotation of the cable retention apparatus 100 upon mounting. In some embodiments, the cable retention member 104 is made of a flexible material to provide sufficient flexibility to adapt the cable retention member 104 to cables of various diameters.

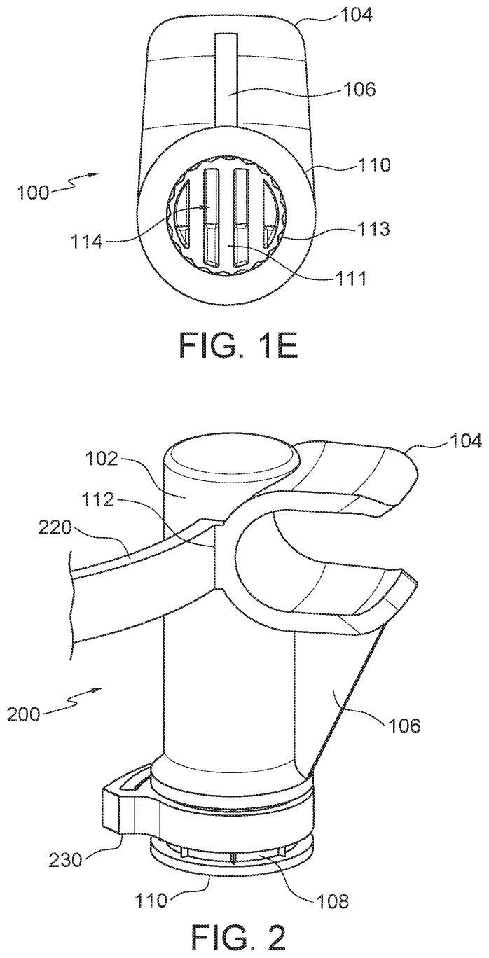

FIG. 2 is a perspective view of a stud-mountable cable retention system 200, in accordance with another exemplary embodiment of the present disclosure. The cable retention system 200 may include the cable retention apparatus 100 of FIG. 1A-1E and its attendant elements, as well as an adjustable fastening member 230 positioned about a periphery of the stud engagement member 108. The adjustable fastening member 230 may be a ratchet-style clamp or other closable fastener. Other alternatives for affixing or fastening the stud engagement member 108 to a stud after the stud engagement member 108 has been placed over the stud include a zip tie, wire clamp, or other cinching or clamping straps or devices.

In some embodiments, the cable retention system 200 may also or alternatively include a cable guide member 220 connected at one end to the body member 102 of the cable retention apparatus 100 and which extends away from the body member 102 in a predetermined or desired direction (e.g., to the right or left, straight or arched, and so forth). In some embodiments, the cable guide member 220 may be integrated with the body member 102 and in other embodiments the cable guide member 220 may be attached or affixed to the body member 102.

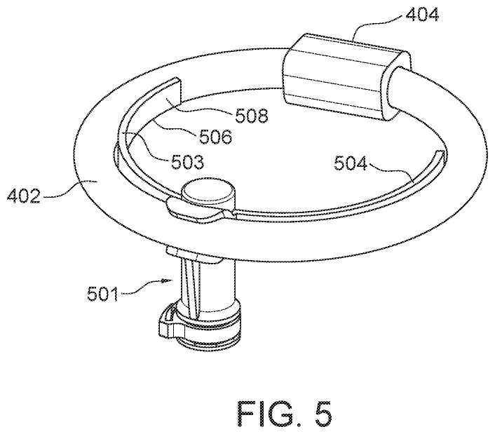

In some embodiments, the cable retention system 200 may include more than one cable guide member 220. For example, with reference to the alternative cable retention system 501 illustrated in FIG. 5, the system 501 may include a first cable guide member 503 connected at one end to the body member 102 of the cable retention apparatus 100 and extending away from the body member 102 in a first direction and a second cable guide member 504 connected at one end to the body member 102 and extending away from the body member 102 in a second direction. The cable guide members 503, 504 may provide or maintain a desired shape to a cable 402 being retained by the cable retention system 501. Each cable guide member 503, 504 may include a wall 508 with optional lower and upper lips or ledges 506 that form a channel to allow the cable to “ride” along the cable guide member 503, 504 and provide additional vertical support to the cable 402. In some embodiments, only a lower lip or ledge 506 may be included, where the cable retention system 501 is installed in a location where gravity will maintain the cable 402 against the lower lip 506.

Where the cable 402 forms part of a Rogowski coil, the cable 402 may include a closing fastener 404 to secure the cable ends together to form a loop. A Rogowski coil is an electrical device used to aid in measuring alternating current (AC) or high-speed current pulses. The Rogowski coil may include a helical coil of wire with the lead from one end returning through the center of the coil to the other end so that both terminals are at the same end of the coil. Other Rogowski coil approaches use a full toroid geometry. The Rogowski coil is wrapped around a straight conductor whose current is to be measured. Although a Rogowski coil is shown as one example of a cable that can be retained by a cable retention apparatus 100 or a cable retention system 200, 501, the embodiments of the present disclosure are not limited to use with Rogowski coils and may be used to retain various other cables, such as coaxial cables, insulated wires, audio cables, video cables, and so forth.

One or more of the cable retention systems 200, 501 described with respect to FIGS. 2 and 5 may be used to retain a cable in place. In some embodiments, one or more stud-mountable cable retention apparatus 100 may be used in any quantity to retain a cable in particular configurations, such as in a circular configuration. Note that the disclosed embodiments are not limited to retaining cables in circular configurations. The shape of the cable guides 220, 503, 504 will define a shape for the cable being retained and a circular shape is merely provided as an example. Furthermore, the cable retention systems 200, 501 are not limited to being used with cable guides 220, 503, 504. They may be used with or without cable guides.

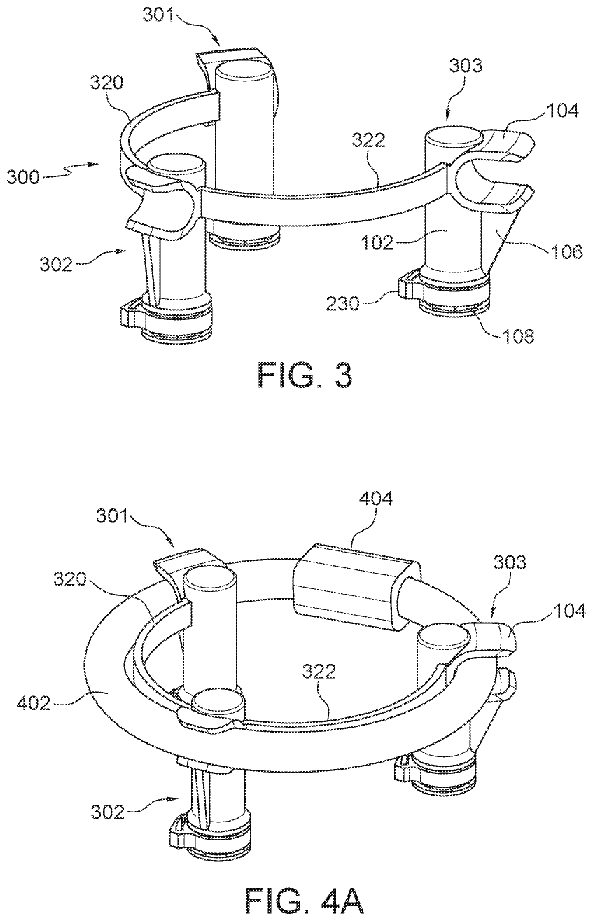

FIG. 3 illustrates an alternative cable retention system 300, in accordance with other exemplary embodiments of the present disclosure. This cable retention system 300 includes a plurality of stud-mountable cable retention devices 301-303 (three shown for illustrative purposes only). Each cable retention device 301-303 may be a cable retention apparatus 100 as described above with respect to FIGS. 1A-1E.

In this embodiment, pairs of cable retention devices are interconnected by one or more respective cable guide members 320, 322. For example, one cable guide member 320 interconnects a first pair of cable retention devices 301, 302 and another cable guide member 322 interconnects a second pair of cable retention devices 302, 303. Where the cable retention system includes only two cable retention devices 301, 302, the cable guide member(s) 320 interconnects a single pair of cable retention devices.

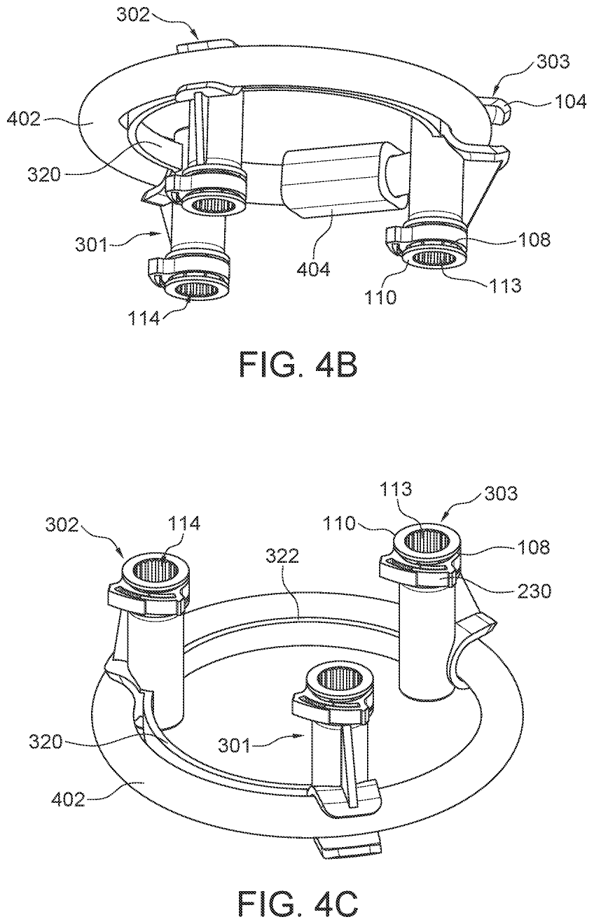

With further reference to FIGS. 4A-4C, the cable retention system 300 of FIG. 3 is shown in use to retain a cable 420, such as a Rogowski coil. As with the other cable retention systems 200, 501 described above, one or more of the cable retention devices 301-303 may optionally include an adjustable fastening member 230 positioned about a periphery of the stud engagement member 108 of the cable retention device 301-303.

In some embodiments, two or more cable retention devices 301-303 may be arranged and configured to maintain a cable (such as cable 402) in a circular configuration about an axis or center point. In some embodiments, three or more cable retention devices 301-303 are arranged and configured to maintain a Rogowski coil (or other cable) in a circular configuration around a primary conductor of a distribution transformer (see FIG. 6) by securing the stud engagement members 108 of the cable retention devices 301-303 to bolt ends of a primary conductor bushing of the distribution transformer. The cable guides 320, 322 in some embodiments may be arc-shaped to guide the retained cable 402 in the circular configuration. The cables guides 320, 322 may be alternatively configured in other shapes to suit a particular cable configuration as desired.

In some embodiments, such as the use case shown in FIG. 6, the cable retention system 300 of FIG. 3 may be used to retain a Rogowski coil 402 around a primary conductor bushing 603 in a pad-mounted distribution transformer 601. The distribution transform 601 has three bolts or threaded ends of bolts 605-607 protruding from an area where the primary conductor bushing 603 is coupled. In the case where a Rogowski coil 402 is to be retained around a conductor 410 (e.g., serving as the high side or primary voltage input cable to the transformer 601), the cable retention devices 301-303 may be secured to the threaded ends of the bolts 605-607 mounting the primary conductor bushing 603 to the tank wall of the transformer 601. As shown in FIG. 5, the cable retention system 501 may be used to retain the Rogowski coil 402 about the primary conductor transformer bushing 603, but additional stability for retaining the cable 402 will typically be achieved by using a cable retention system 300 with two or more cable retention devices 301-303 as shown in FIGS. 4A-4C. For a transformer bushing 603 as shown in FIG. 6, a cable retention system 300 with three cable retention devices 301-303 may provide the most reliable solution. If a particular transformer or other device has more studs, then additional cable retention devices may be included in the cable retention system.

It is to be appreciated that the present disclosure includes methods for forming stud mountable cable retention systems suitable to be attached to any of the objects described herein and other objects which are not necessarily limited to power transformers.

The terminology used herein is for the purpose of describing particular embodiments only and is not intended to be limiting. The terms “a” or “an,” as used herein, are defined as one or more than one. The term “plurality,” as used herein, is defined as two or more. The term “another,” as used herein, is defined as at least a second or more. The terms “including” and/or “having,” as used herein mean “include, but not limited to.” The term “providing” is defined herein in its broadest sense (e.g., bringing/coming into physical existence, making available, and/or supplying to someone or something, in whole or in multiple parts at once or over a period of time).

As used in this description, unless otherwise specified, azimuth or positional relationships indicated by terms such as “up”, “down”, “left”, “right”, “inside”, “outside”, “front”, “back”, “head”, “tail” and so on, are azimuth or positional relationships based on the drawings, which are only to facilitate description of the embodiments of the present disclosure and simplify the description, but not to indicate or imply that the devices or components must have a specific azimuth, or be constructed or operated in the specific azimuth, which thus cannot be understood as a limitation to the embodiments of the present disclosure or the appended claims. Furthermore, terms such as “first”, “second”, “third” and so on are only used for identification purposes and are not to be construed as indicating or implying relative importance.

As used in this description, unless otherwise clearly defined and limited, terms such as “installed”, “coupled”, and “connected” should be broadly interpreted, for example, to mean fixedly connected, detachably connected, integrally connected; mechanically connected, electrically connected; directly connected, or indirectly connected via an intermediate medium.

In the absence of any specific clarification related to its express use in a particular context, where the terms “substantially,” “approximately,” “generally,” or “about” are used as modifiers in the present disclosure and any appended claims (e.g., to modify a structure, a dimension, a measurement, a direction, an orientation, or any other characteristic), it is understood that the characteristic may vary by up to thirty percent. In these cases, a device that is mounted exactly orthogonal is mounted along a “Y” axis and a “X” axis that is normal (i.e., 90 degrees or at right angle) to a plane or line formed by a “Z” axis. Different from the exact precision of the term “orthogonal,” the use of “substantially” or “about” to modify the characteristic permits a variance of the particular characteristic by up to thirty percent or such other amount as may be required by the context of the applicable description. As another example, an element or component that is oriented exactly opposite to another element or component is oriented one hundred eighty degrees from the other element or component. Different from the exact precision of the term “opposite,” the use of “substantially” or “generally” to modify the orientation or direction permits a variance thereof by up to thirty percent (e.g., up to fifty-four degrees) or such other amount as may be stated in the applicable description or required by the context of the applicable description. Alternatively, these terms may refer to a range of numbers or quantities that one of skill in the art would consider equivalent to the recited values (i.e., having the same function or result). In many instances, these terms may include numbers that are rounded to the nearest significant figure.

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items or ideas and one or more other alternative embodiments that include fewer than all of the associated items or idea.

As the context may require in this disclosure, except as the context may dictate otherwise, the singular shall mean the plural and vice versa. Also, the masculine shall mean the feminine and vice versa.

The various embodiments described above may be combined to provide further embodiments and aspects of embodiments may be modified to employ concepts of patents, applications and publications to provide further embodiments.

What is claimed is:

1. A stud-mountable cable retention apparatus comprising:
a cable retention member;
a stud engagement member defining a cavity therein; and
a body member interconnecting the cable retention member and the stud engagement member.

2. The cable retention apparatus of claim 1, wherein the cable retention member is generally C-shaped and the cavity is generally cylindrically shaped.

3. The cable retention apparatus of claim 2, further comprising:
a support member interconnecting the body member and an end portion of the cable retention member.

4. The cable retention apparatus of claim 1, further comprising:
a stop member arranged within the cavity of the stud engagement member, the stop member being positioned a predetermined distance from an opening of the cavity.

5. The cable retention apparatus of claim 1, further comprising:
a flange member coupled to an end of the stud engagement member so as to encircle an opening of the cavity of the stud engagement member.

6. The cable retention apparatus of claim 1, wherein an outside surface of the stud engagement member includes at least one rib element.

7. The cable retention apparatus of claim 1, wherein at least the cable retention member and the stud engagement member are constructed of a material that is pliable and has a high coefficient of friction.

8. The cable retention apparatus of claim 7, wherein the material includes silicone rubber.

9. The cable retention apparatus of claim 1, wherein a diameter of the cavity of the stud engagement member is approximately equal to a smallest diameter of a stud to which the cable retention apparatus will be mounted.

10. The cable retention apparatus of claim 1, wherein a wall of the cavity of the stud engagement member includes a plurality of protrusions.

11. A stud-mountable cable retention system comprising:
a cable retention member;
a stud engagement member defining a cavity therein;
a body member interconnecting the cable retention member and the stud engagement member; and
an adjustable fastening member positioned about a periphery of the stud engagement member.

12. The cable retention system of claim 11, further comprising:
a cable guide member connected at one end to the body member and extending away from the body member in a predetermined direction.

13. The cable retention system of claim 11, wherein the adjustable fastening member is a ratchet-style clamp.

14. The cable retention system of claim 11, wherein the cable retention member is generally C-shaped and the cavity is generally cylindrically shaped.

15. The cable retention system of claim 14, further comprising:
a support member interconnecting the body member and an end portion of the cable retention member.

16. The cable retention system of claim 11, further comprising:
a first cable guide member connected at one end to the body member and extending away from the body member in a first predetermined direction; and
a second cable guide member connected at one end to the body member and extending away from the body member in a second predetermined direction.

17. A cable retention system comprising:
a plurality of stud-mountable cable retention devices, each cable retention device including:
a cable retention member;
a stud engagement member defining a cavity therein; and
a body member interconnecting the cable retention member and the stud engagement member; and
at least one cable guide member interconnecting a pair of cable retention devices of the plurality of cable retention devices.

18. The cable retention system of claim 17, wherein:
the plurality of cable retention devices includes a first cable retention device, a second cable retention device, and a third cable retention device;
the least one cable guide member includes a first cable guide member and a second cable guide member;
the first cable guide member is arch-shaped and interconnects the first cable retention device and the second cable retention device; and
the second cable guide member is arch-shaped and interconnects the second cable retention device and the third cable retention device.

19. The cable retention system of claim 17, wherein a diameter of the cavity of the stud engagement member is approximately equal to a smallest diameter of a threaded end of a bolt used to fasten a primary conductor bushing within a pad-mounted distribution transformer.

20. The cable retention system of claim 17, wherein each cable retention device further includes an adjustable fastening member positioned about a periphery of the stud engagement member.
